(19) United States
(12) Patent Application Publication
(10) Pub. No.: US 2014/0285987 A1
(43) Pub. Date: Sep. 25, 2014

(54) ELECTRONIC CONTROL DEVICE

(71) Applicant: HITACHI AUTOMOTIVE SYSTEMS, LTD., Hitachinaka-shi (JP)

(72) Inventors: Kazuaki Nagashima, Kiryu-shi (JP); Susumu Kaneko, Isesaki-shi (JP)

(73) Assignee: HITACHI AUTOMOTIVE SYSTEMS, LTD., Hitachinaka-shi (JP)

(21) Appl. No.: 14/025,367

(22) Filed: Sep. 12, 2013

(30) Foreign Application Priority Data
Mar. 21, 2013 (JP) 2013-058885

(51) Int. Cl. H05K 7/12

(52) U.S. Cl. CPC H05K 7/12
USPC 361/759

(57) ABSTRACT

An electronic control device having a circuit board has: an enclosure formed from a plurality of enclosure members and accommodating the circuit board inside the enclosure; and a plurality of snap-fits separately arranged at the enclosure member to hold the circuit board. The snap-fit has a supporter elastically supporting one end surface of the circuit board; and a supporting hook supporting the other end surface of the circuit board. When a sensor terminal is pressed against the one end surface of the circuit board through a contact pad at least one of snap-fit arrangement positions, the supporter of the snap-fit positioned where the sensor terminal is pressed against the one end surface of the circuit board has a plurality of elastically-supporting parts that make elastic contact with the one end surface of the circuit board at dispersed positions with respect to a circumferential edge side of the contact pad.

### BACKGROUND OF THE INVENTION

The present invention relates to an electronic control device to control, for instance, an anti-lock brake system (ABS) of a vehicle.

As the electronic control device used for the anti-lock brake system (ABS) of the vehicle, for instance, it is provided at a hydraulic pressure control block that conducts electricity to a vehicle body and mounts various hydraulic pressure control equipment such as a hydraulic pressure control solenoid (a pressure boosting valve and a pressure reducing valve) and various kinds of sensors. The electronic control device has a circuit board mounting thereon electronic components that drive the various hydraulic pressure control equipment and perform signal processing of the various kinds of sensors, and the circuit board is accommodated in a space inside an enclosure that is formed from a plurality of enclosure members (e.g. after-mentioned base member and cover member). Such configuration has been disclosed in, for instance, Japanese Patent Provisional Publication No. 2008-174218 (hereinafter is referred to as “JP2008-174218”).

As the structure holding the circuit board in the space inside the enclosure, it could be a structure in which the circuit board is fixed by a snap-fit, and for instance, Japanese Patent Provisional Publication No. 2012-099708 (hereinafter is referred to as “JP2012-099708”) discloses a snap-fitting structure using a supporter (a forcing portion) and a supporting hook (a stopper portion). In JP2012-099708, the supporter elastically supports one end surface of the circuit board, and the supporting hook catches and holds the other end surface, which is an opposite side to the one end surface, of the circuit board at a position corresponding to an elastically supported position of the one end surface.

### SUMMARY OF THE INVENTION

In the snap-fitting structure of JP2012-099708 in which, as described above, the circuit board is held by the snap-fit having the supporter etc. that merely elastically supports the one end surface of the circuit board, however, for example, in a case where a sensor terminal makes contact with the circuit board by being pressed against the circuit board (e.g. through a contact pad), there is a risk that the circuit board will strain by a pressing force of the sensor terminal.

It is therefore an object of the present invention to provide an electronic control device that is capable of holding the circuit board with the strain of the circuit board by the pressing force of the sensor terminal suppressed while suppressing vibration and wobble of the circuit board.

According to one aspect of the present invention, an electronic control device having a circuit board on which electronic components are mounted, the electronic control device comprises: an enclosure formed from a plurality of enclosure members and accommodating the circuit board in a space inside the enclosure; and a plurality of snap-fits separately arranged at the enclosure member to hold the circuit board. The snap-fit has (a) a supporter that elastically supports one end surface of the circuit board; and (b) a supporting hook that supports the other end surface of the circuit board. And when a sensor terminal is pressed against the one end surface of the circuit board through a contact pad at least one of snap-fit arrangement positions, the supporter of the snap-fit positioned where the sensor terminal is pressed against the one end surface of the circuit board has a plurality of elastically-supporting parts that make elastic contact with the one end surface of the circuit board at dispersed positions with respect to a circumferential edge side of the contact pad.

According to the present invention, it is possible to hold the circuit board with the strain of the circuit board by the pressing force of the sensor terminal suppressed while suppressing the vibration or the wobble of the circuit board.

The other objects and features of this invention will become understood from the following description with reference to the accompanying drawings.

### BRIEF DESCRIPTION OF THE DRAWINGS

FIG. 1 is a perspective exploded view, viewed from an upper side, showing an example of an electronic control device of the present embodiments.

FIG. 2 is a local sectional view of the electronic control device of FIG. 1.

FIG. 3 is a perspective view showing another example of the electronic control device of the present embodiments.

FIG. 4 is a schematic view showing an example of a printed circuit board that is applied to the electronic control device of FIG. 3.

FIGS. 5A and 5B are perspective views schematically showing an example of a snap-fit of the present embodiments. (No circuit board is present in FIG. 5A. A circuit board is present in FIG. 5B)

FIGS. 6A and 6B are drawings for explaining the snap-fit of FIGS. 5A and 5B. (FIG. 6A is a schematic view to of the snap-fit. FIG. 6B is a schematic sectional view, viewed from a right hand side of FIG. 6A, of the snap-fit.)

FIGS. 7A and 7B are drawings for explaining another example of the snap-fit. (FIG. 7A is a schematic view of the snap-fit. FIG. 7B is a schematic sectional view, viewed from a right hand side of FIG. 7A, of the snap-fit.).

FIGS. 8A and 8B are drawings for explaining another example of the snap-fit. (FIG. 8A is a schematic view of the snap-fit. FIG. 8B is a schematic sectional view, viewed from a right hand side of FIG. 8A, of the snap-fit.).

FIGS. 9A and 9B are drawings for explaining another example of the snap-fit. (FIG. 9A is a schematic view of the snap-fit. FIG. 9B is a schematic sectional view, viewed from a right hand side of FIG. 9A, of the snap-fit.).

FIGS. 10A and 10B are drawings for explaining another example of the snap-fit. (FIG. 10A is a schematic view of the snap-fit. FIG. 10B is a schematic sectional view, viewed from a right hand side of FIG. 10A, of the snap-fit.).

FIG. 11 is a drawing for explaining another example of the snap-fit.

### DETAILED DESCRIPTION OF THE INVENTION

Embodiments of an electronic control device of the present invention will now be explained below with reference to the drawings.

To hold the circuit board, the electronic control device of the present invention does not employ the snap-fit, like the JP2012-099708, having the supporter (the forcing portion) that merely elastically supports the one end surface of the circuit board, but employs a structure holding the circuit board with the circuit board elastically supported according to a press-contact position of the sensor terminal.

That is, in a configuration in which a plurality of snap-fits are separately arranged to hold the circuit board and the sensor terminal is pressed against the one end surface of the circuit board through the contact pad at least one of snap-fit arrangement positions, the supporter of the snap-fit positioned at the sensor terminal press-contact position (i.e. positioned where the sensor terminal is pressed against the one end surface of the circuit board) has a plurality of elastically-supporting parts that make elastic contact with the one end surface of the circuit board at separated or dispersed positions with respect to a circumferential edge side of the contact pad.

As described above, the circuit board is held by the plurality of snap-fits and the plurality of elastically-supporting parts of the snap-fit positioned at the sensor terminal press-contact position make elastic contact with a circumferential edge of the contact pad, thereby suppressing the wobble and the vibration (caused by the fact that the vehicle operates and travels) of the circuit board and suppressing the strain of the circuit board due to the pressing force of the sensor terminal. This contributes to an increase in durability of the electronic control device.

In a related art electronic control device, the circuit board and the sensor are connected through a busbar, for instance, the circuit board and the sensor are connected using a so-called busbar unit that is formed as a single block by molding a plurality of busbars. This configuration avoids the sensor terminal being directly pressed against the circuit board. However, in the case of this configuration, although there is no occurrence of the strain of the circuit board, parts count might increase and also a size of the electronic control device (e.g. a size in a thickness direction of the busbar unit) might increase due to the fact that the busbar unit is used.

In contrast to this, although it is conceivable that, in order to suppress the strain of the circuit board, the circuit board is fixed with screws at a plurality of positions on the circuit board, this manner requires a plurality of screws and parts count associated with the screw fixing might increase.

On the other hand, according to the present embodiments of the present invention, the wobble and the vibration of the circuit board can be adequately suppressed, and the strain of the circuit board by the pressing force of the sensor terminal can be suppressed even without using such busbar and screw. This contributes to size reduction of the electronic control device and reduction of products cost.

The snap-fits are properly arranged separately from each other so as not to interfere with various parts such as electronic components and a pressure sensor which are mounted on the circuit board. The snap-fits arranged at the positions except the sensor terminal press-contact position are arranged to hold the circuit board so as to suppress the wobble and the vibration of the circuit board. For instance, in a case where a power connecter terminal is connected to a part of the circuit board, even if no snap-fit is arranged at this connecting point, since each of the snap-fits is separately arranged at a position spaced a certain distance apart from this connecting point, the circuit board is held with an adequate supporting force by these snap-fits. As an example, in a case where the power connecter terminal is connected at a one side circumferential edge of four sides of the flat circuit board and also a depressed portion that is depressed toward the middle of the circuit board in a plane direction of the circuit board is formed at a circumferential edge located between an opposite side circumferential edge that is opposite to the one side circumferential edge and the power connecter terminal, for instance, a plurality of snap-fits are separately arranged on the opposite side of the depressed portion (i.e. on one side with respect to the depressed portion) at three side circumferential edges except the one side circumferential edge where the power connecter terminal is connected.

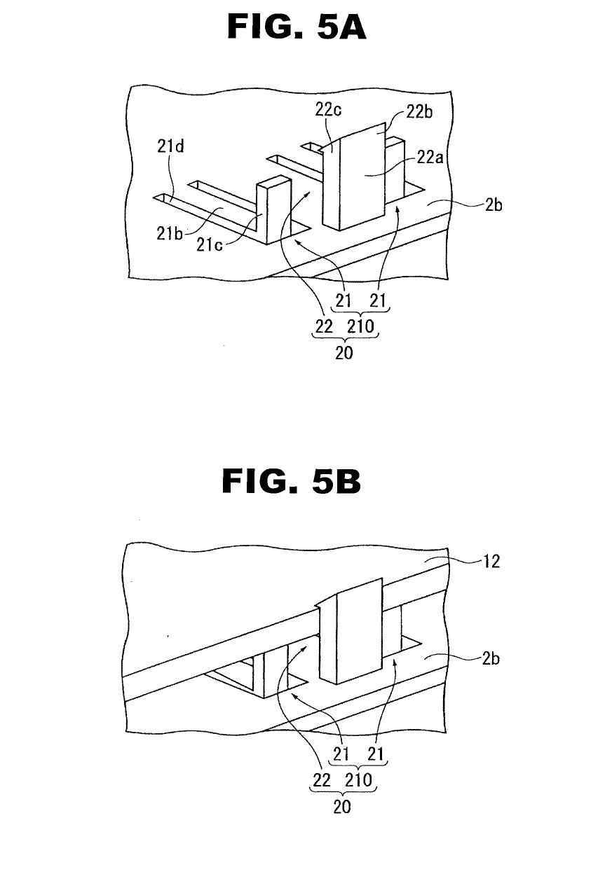

Each snap-fit can be modified as long as the snap-fit is provided in an enclosure of the electronic control device so as to hold the circuit board in a snap-fitting manner and has the supporter that elastically supports the one end surface of the circuit board and a supporting hook that supports the other end surface of the circuit board. For instance, it is a snap-fit 20 as shown in FIGS. 5A and 5B. The snap-fit 20 has a supporter 210 and a supporting hook 22 which, by an integral molding or an insert molding, are formed integrally with an enclosure member (e.g. an after-mentioned mid-bottom wall section) 2b that spreads or extends along the one end surface of the circuit board (an after-mentioned printed circuit board) 12 with a certain distance provided from the one end surface of the circuit board. Instead of forming the supporter 210 and the supporting hook 22 by the integral molding or the insert molding, the supporter 210 and the supporting hook 22 could be fixed to the enclosure member 2b.

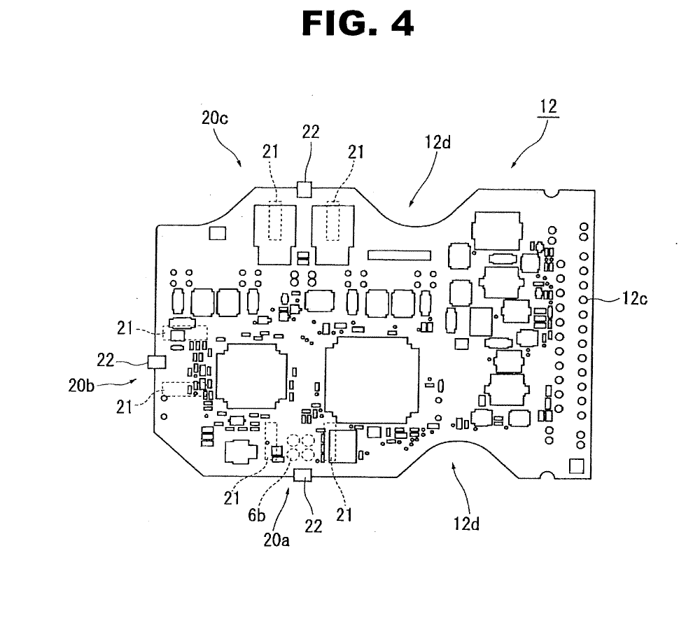

With regard to the supporter 210 of the snap-fit arranged at the sensor terminal press-contact position, it has the plurality of elastically-supporting parts. For instance, as shown in FIGS. 5A and 5B, a plurality of elastically-supporting parts 21 are provided at the enclosure member (e.g. the mid-bottom wall section) 2b and make elastic contact with the one end surface of the circuit board 12 at separated or dispersed positions with respect to the circumferential edge side of the contact pad (e.g. a contact pad 6b in FIGS. 2 and 4) for the sensor terminal press-contact.

Here, the supporter 210 of the snap-fit arranged at the position except the sensor terminal press-contact position could also have the plurality of elastically-supporting parts (which make elastic contact with the one end surface of the circuit board 12 at separated or dispersed positions irrespective of the contact pad). This structure facilitates the suppression of the wobble and the vibration of the circuit board.

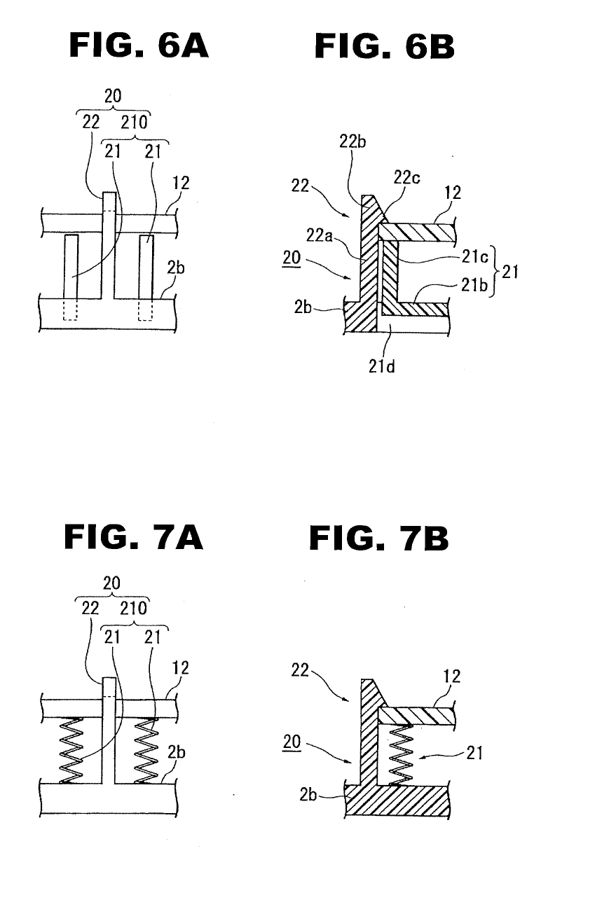

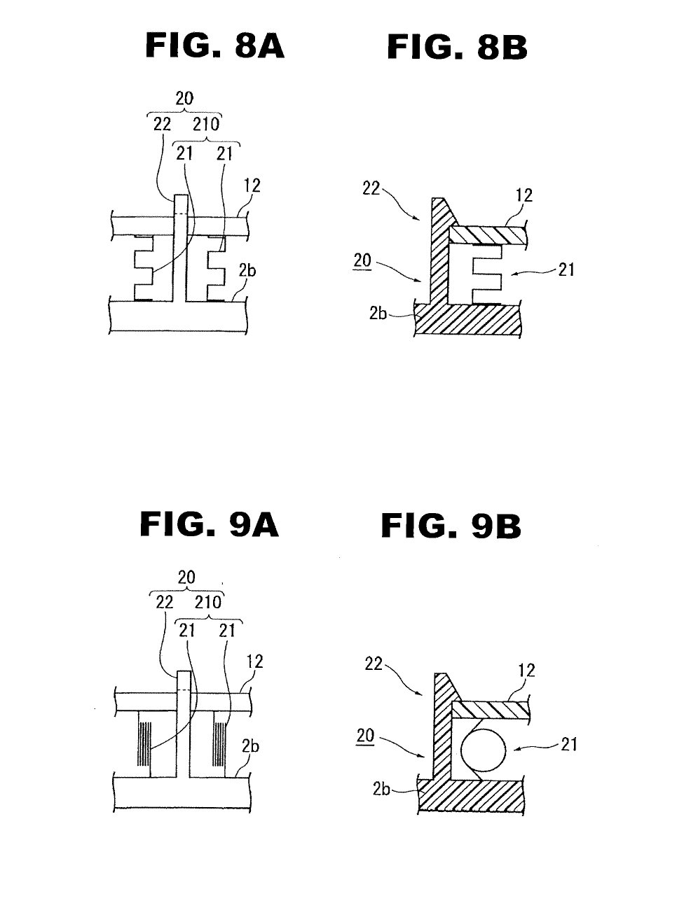

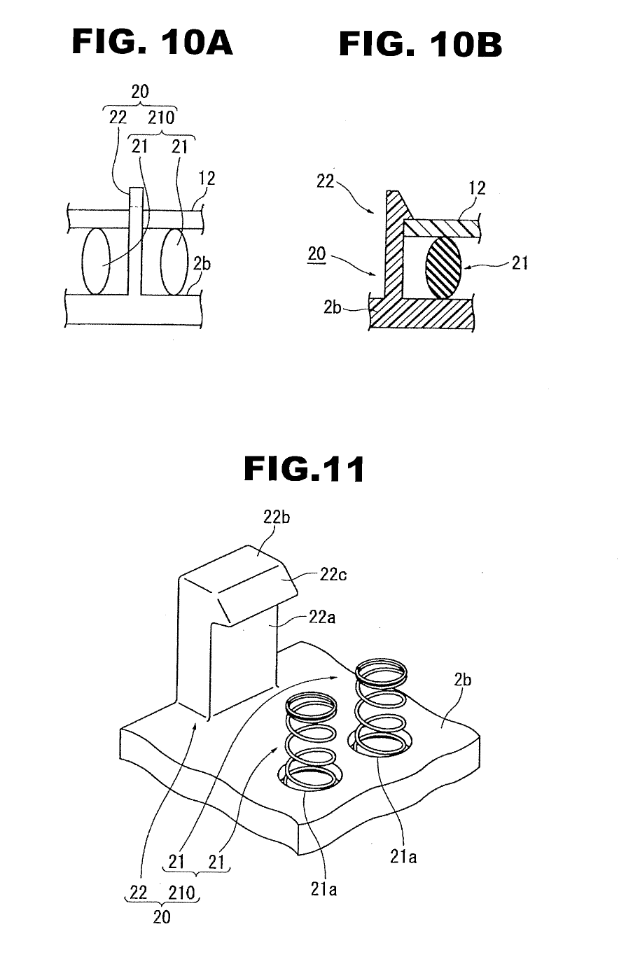

With respect to the supporter 210 having the plurality of elastically-supporting parts, various kinds of elastically-supporting parts could be used as long as the elastically-supporting part elastically supports the one end surface of the circuit board. For example, as shown in FIGS. 6A and 6B to 9A and 9B, the supporter 210 has various shapes of the elastically-supporting parts 21 such as cantilever shape (FIGS. 5A and 5B also show the cantilever shaped elastically-supporting parts), coil shape, plate spring shape and torsion coil spring shape. In addition, as shown in FIGS. 10A and 10B, the supporter 210 could have the elastically-supporting parts 21 that are merely formed from an elastic material block (e.g. an ellipse or oval molded block).

In the case of the supporter 210 of the snap-fit arranged at the sensor terminal press-contact position, as described above, the supporter 210 has the plurality of elastically-supporting parts 21 (in FIGS. 5A and 5B to 10A and 10B, the number of the elastically-supporting parts 21 is two), and one end side (an elastic contact side) of each elastically-supporting part 21 makes elastic contact with the one end surface of the circuit board 12 at the separated or dispersed positions with respect to the circumferential edge side of the contact pad.

The supporter 210 having such elastically-supporting parts 21 is formed integrally with the enclosure member by the integral molding or the insert molding or fixed to the enclosure member as described above, and one end side (that is opposite to the above one end side corresponding to the elastic contact side) of the elastically-supporting part 21 is fixedly supported by the enclosure member.

As an example of this fixedly-supporting manner, in the case of the elastically-supporting part 21 shown in FIGS. 7A and 7B to 10A and 10B, as illustrated in FIG. 11, connecting holes (in FIG. 11, they are subsidence holes) 21a to which the one end sides of the elastically-supporting parts 21 can be connected (fitted or press-fitted) are formed at predetermined fixing supporting positions on a surface of the enclosure member 2b. Then, by connecting the one end sides of the elastically-supporting parts 21 to the connecting holes 21a, the elastically-supporting part 21 is fixed to and supported by the enclosure member 2b.

Instead of forming the connecting holes 21a, positioning protrusions could be formed on respective circumferential edge sides of the fixing supporting positions (for instance, circumferential walls surrounding the respective circumferential edges are formed), then each one end side of the elastically-supporting part 21 is positioned at an inner side of the positioning protrusion (i.e. at the fixing supporting position) and fixed to and supported by the enclosure member 2b.

Further, in the case of the elastically-supporting part 21, as shown in FIGS. 7A and 7B to 9A and 9B, which can be obtained by shaping long-length material (e.g. a wire) into the elastic shape (e.g. the coil shape, the plate spring shape and the torsion coil spring shape), instead of forming the connecting holes, protrusions could be formed on the surface of the enclosure member 2b, then each one end side of the elastically-supporting part 21 is wound or coiled around the protrusion and fixed to and supported by the enclosure member 2b.

Furthermore, in the case of the cantilever shaped elastically-supporting parts 21 shown in FIGS. 5A and 5B and 6A and 6B, as illustrated in the drawings, the elastically-supporting part 21 has a cantilever portion 21b that extends along the one end surface of the circuit board 12 and a protruding portion 21c that protrudes from a top end side of the cantilever portion 21b in a direction of the one end surface of the circuit board 12, then the elastically-supporting part 21 is fixed to and supported by the enclosure member 2b through the cantilever portion 21b.

This cantilever portion 21b is formed, for instance, by forming slit grooves (e.g. penetration grooves) 21d at an area on the surface of the enclosure member 2b where the cantilever portion 21b is formed, so as to enclose three sides of four sides of the area. In this forming manner, the cantilever portion 21b is fixed to and supported by the remaining one side of the enclosure member 2b.

As explained above, the fixedly-supporting structure of the elastically-supporting part 21 of the supporter 210 is not especially limited, and various kinds of fixing manner can be employed.

As for the supporting hook 22, various structures of supporting hook could be used as long as the supporting hook 22 has an elastic hook shape like a so-called snap hook that is capable of elastic deformation and supports the other end surface of the circuit board 12 whose one end surface is elastically supported by the supporter 210 having the elastically-supporting part 21. For instance, as shown, as the supporting hook 22, in FIGS. 5A and 5B to FIG. 11, the supporting hook 22 has a pillar portion or a column portion 22a that extends from the enclosure member 2b in a direction of the circuit board 12, and a top end portion 22b of the column portion 22a protruding from the enclosure member 2b at a circumferential edge side (an outer edge side) of the circuit board 12 is fitted on (and catches and holds) the circumferential edge on the other end surface of the circuit board 12.

As mentioned above, shape of the top end portion of the supporting hook 22, which is fitted on the circumferential edge on the other end surface of the circuit board 12, can be modified. For example, in the case of the supporting hook 22 standing on the enclosure member 2b as shown in FIGS. 5A and 5B to FIG. 11, the top end portion 22b of the column portion 22a protruding from the enclosure member 2b at the circumferential edge side of the circuit board 12 is provided with a nail portion 22c that sticks out or overhangs toward the middle of the circuit board 12 along the other end surface of the circuit board 12. Then, the nail portion 22c is fitted on (and catches and holds) the circumferential edge on the other end surface of the circuit board 12.

Shape of the nail portion 22c is not especially limited. For instance, a lower surface of the nail portion 22c could be formed, as a connecting or fitting surface to the other end surface of the circuit board 12, so as to tilt in a downward direction. Or, an upper surface of the nail portion 22c might be smoothly curved in an upward direction so as to have a guiding function.

Additionally, the fitting surface of the lower surface of the nail portion 22c is not formed so as to tilt in the downward direction as shown in FIGS. 5A and 5B to FIG. 11, but the lower surface of the nail portion 22c could be formed so as to spread along the other end surface of the circuit board 12 and hold the circuit board 12 by an area joint (plane contact) to the other end surface of the circuit board 12. With this fitting structure, a contact area between the nail portion 22c and the other end surface of the circuit board 12 increases, thereby supporting and holding the circuit board 12 more stably.

Regarding the sensor terminal being pressed against the circuit board, various kinds of the sensor terminals are conceivable according to application of the electronic control device. For instance, in the case where the electronic control device is applied to the anti-lock brake system (ABS), the pressure sensor (a hydraulic pressure sensor) that detects a hydraulic pressure and sends a signal to the circuit board is mounted, and its sensor terminal makes contact with the circuit board by being pressed against the circuit board through the contact pad. Material and shape of the contact pad and the number of the contact pads are not especially limited, and they can be changed according to shape and press-contact position of the sensor terminal and the number of the sensor terminals. By arranging the elastically-supporting parts 21 of the snap-fits so that the contact pad is encircled by elastic contact positions of the elastically-supporting parts 21, for instance, by arranging the elastically-supporting parts 21 so that the contact pad is located between at least two elastic contact positions of the elastically-supporting parts 21, the strain of the circuit board by the pressing force of the sensor terminal can be suppressed with a good supporting valance.

The electronic control device of the present invention can be applied to various devices without limiting to the anti-lock brake system (ABS). As described above, is the electronic control device of the present invention brings about beneficial effects to the devices using the sensor terminal being pressed against the circuit board through the contact pad. As an example of the devices, it is an electronic control device that is applied to a traction control device.

<Configuration of Electronic Control Device>

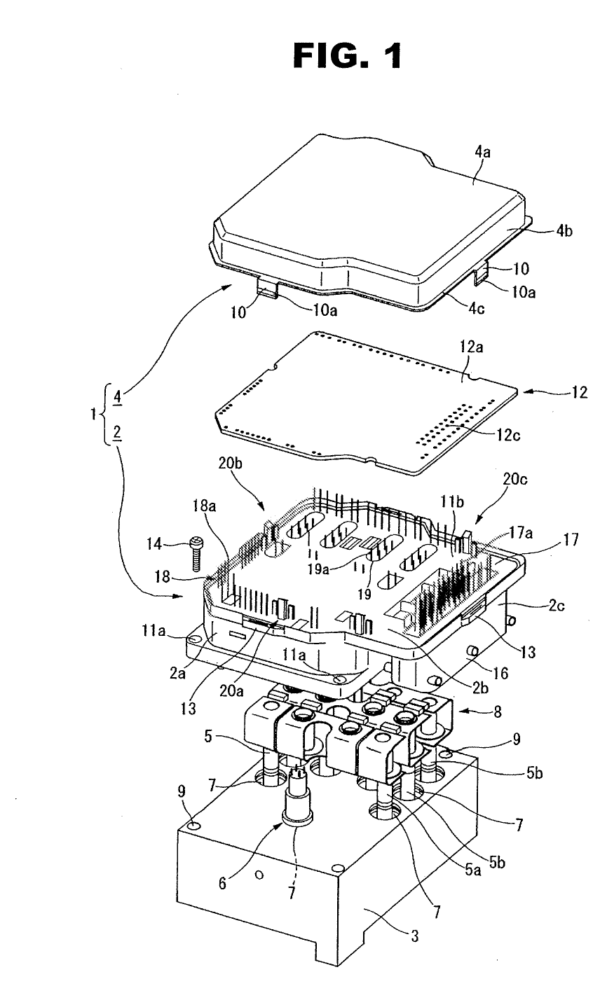

In the following description, the electronic control device of the present embodiments, which is applied to the anti-lock brake system (ABS) of the vehicle, will be explained below with reference to FIGS. 1 and 2.

First, general outlines of the anti-lock brake system will be explained. The anti-lock brake system has a master cylinder that produces a brake pressure according to driver's brake pedal depression amount, a main oil passage that connects the master cylinder and each wheel cylinder of front right and left wheels (FR, FL) and rear right and left wheels (RR, RL), after-mentioned normally-open solenoid type pressure boosting valve and normally-closed solenoid type pressure reducing valve that are provided on the main oil passage and control a brake fluid pressure applied from the master cylinder to each wheel cylinder, a plunger pump that is provided on the main oil passage and discharges a brake fluid pressure to each wheel cylinder, a reservoir tank that stores, through the pressure reducing valve, brake fluid discharged from each wheel cylinder and supplies the brake fluid to the main oil passage by an operation of the plunger pump, and a pressure sensor.

The pressure boosting valve is configured to control the brake fluid pressure applied from the master cylinder so as to be able to supply it to each wheel cylinder in a normal braking operation. The pressure reducing valve is configured to open when an internal pressure of each wheel cylinder becomes a predetermined pressure or greater and slip of a wheel occurs, and return the brake fluid to the reservoir tank. Open/close of these pressure boosting valve and pressure reducing valve are controlled through the electronic control device (described later), then boost, reduction and hold of the brake fluid pressure in each wheel cylinder are controlled. The pressure boosting valve and the pressure reducing valve are configured to open/close by current-supply based on a control signal from the electronic control device.

The pressure sensor senses the brake fluid pressure and sends a sensor signal to the electronic control device for the control of the open/close operation of the pressure boosting valve and the pressure reducing valve.

Next, the electronic control device shown in FIGS. 1 and 2 will be explained. The electronic control device has the printed circuit board (the circuit board) 12 on which electronic components are mounted. The printed circuit board 12 is accommodated in a space inside an enclosure 1 that is formed from a base member 2 and a cover member 4. The enclosure 1 is secured to a lower side hydraulic pressure control block 3 that conducts electricity to a vehicle body.

The hydraulic pressure control block 3 is formed as a single block into a substantially cubic shape from, for instance, an aluminium alloy. The hydraulic pressure control block 3 is provided at an upper surface side thereof with a plurality of holding holes 7 that are formed in a vertical direction. Lower sections of a plurality of pressure boosting valve 5a, pressure reducing valve 5b and pressure sensor 6 are inserted into the holding holes 7, and are held by the holding holes 7. Further, the hydraulic pressure control block 3 supports a coil unit 8 that is connected to each upper end of the pressure boosting valve 5a and the pressure reducing valve 5b.

In addition, a hydraulic unit (its detailed explanation is omitted here), formed from e.g. main and sub oil passages connecting to the pressure boosting valve 5a, the pressure reducing valve 5b and the pressure sensor 6 and the plunger pump supplying the brake fluid pressure to the main oil passage, is provided inside the hydraulic pressure control block 3. Also, as shown in FIG. 2, an electric motor M that drives the plunger pump is fixed to a lower side of the hydraulic pressure control block 3.

The upper surface side of the hydraulic pressure control block 3 is provided at four corners thereof with female screw holes 9 into which fixing bolts 14 are screwed.

Here, instead of the plunger pump, a reversible gear pump could be used.

The cover member 4 is formed into a thin dished shape along an outside shape of the hydraulic pressure control block 3 from, for instance, an aluminium alloy having heat dissipation (heat radiation) and serving as a heat sink. The cover member 4 is formed from a flat upper wall 4a, a substantially rectangular looped side wall 4b that is formed integrally with an outer circumferential edge of the upper wall 4a and a rectangular-frame-shaped flange 4c that is continuously formed integrally with an lower edge outer circumference of the side wall 4b.

The flange 4c is provided with four stopper pieces 10 that protrude downwards. These four stopper pieces 10 connect to or catch an upper edge outer circumference of the base member 2 when the base member 2 is covered by the cover member 4 with the printed circuit board 12 accommodated in the cover member 4. Each stopper piece 10 is disposed at a substantially middle position in a longitudinal direction of respective sides of the flange 4c. As can be seen in FIG. 1, the stopper piece 10 has, at a top end outer side thereof, a stopper nail 10a.

The base member 2 is a substantially box-shaped member and is located between the hydraulic pressure control block 3 and the cover member 4. The base member 2 has a tubular circumferential wall section 2a, the flat plate mid-bottom wall section 2b that covers an upper end side opening of the circumferential wall section 2a and spreads in a horizontal direction and a connecter wall section 2c that is a circumferential edge part protruding from the circumferential wall section 2a in the horizontal direction and located at a lower surface side of the mid-bottom wall section 2b.

The tubular circumferential wall section 2a stands in the to vertical direction so as to surround four sides of the upper surface side of the hydraulic pressure control block 3, and protects projecting portions of the pressure boosting valve 5a, the pressure reducing valve 5b and the pressure sensor 6.

The connecter wall section 2c has a structure in which a power connecter connected to a battery, a motor connecter to supply power to the electric motor M, a signal connecter that is a signal path for a resolver, CAN communication and I/O are connected.

The printed circuit board 12, which is the circuit board, to control the electric motor M etc. is set on the mid-bottom wall section 2b.

The base member 2 is formed as an integral block plate from the circumferential wall section 2a, the mid-bottom wall section 2b and the connecter wall section 2c, from, for instance, synthetic resin material by molding. As shown in FIG. 1, an outside shape of the base member 2 is formed into a substantially rectangular shape along outside shapes of the hydraulic pressure control block 3 and the cover member 4.

The base member 2 is provided at the upper edge outer circumference thereof with four connecting portions 13 that are formed integrally with the base member 2. The stopper nail 10a of the stopper piece 10 of the cover member 4 is inserted into an inner side penetration hole of the connecting portion 13 and is elastically connected or fitted to the connecting portion 13. Further, the base member 2 is provided at corners of the outer circumference thereof with bolt insertion holes 11a into which the plurality of fixing bolts 14 are inserted. Each bolt insertion hole 11a penetrates the outer circumference corner of the base member 2 in the vertical direction, and the fixing bolt 14 is inserted into this bolt insertion hole 11a.

On the other hand, as shown in FIG. 2, the base member 2 is provided at a lower edge outer circumference thereof with a fitting groove, and a ring-shaped seal 15 that seals a gap between the base member 2 and the hydraulic pressure control block 3 by making elastic contact with an upper surface side outer circumference of the hydraulic pressure control block 3 is fixed in the fitting groove.

As can be seen in FIG. 1, a terminal group 17 to which the power connecter, the motor connecter and the signal connecter are connected, a terminal group 18 for a control signal to drive a motor relay and a semiconductor switching element (FET) and a terminal group 19 connecting to the pressure boosting valve 5a and the pressure reducing valve 5b etc. penetrate the mid-bottom wall section 2b, then the terminal groups 17, 18 and 19 project from an upper surface 11b of the mid-bottom wall section 2b.

Further, to support and hold the printed circuit board 12, the plurality of snap-fits 20 (in FIGS. 1 and 2, snap-fits 20a to 20c), each of which has the cantilever portion 21b and the protruding portion 21c as shown in FIGS. 5A and 5B and 6A and 6B, are formed integrally with the mid-bottom wall section 2b at three side predetermined positions, except one side of the terminal group 17 side, of four sides of a circumferential edge on the upper surface 11b of the mid-bottom wall section 2b.

Here, in order that the top end sides of the pressure boosting valve 5a, the pressure reducing valve 5b and the pressure sensor 6 do not interfere with the mid-bottom wall section 2b, the mid-bottom wall section 2b is provided with penetration holes as shown in FIG. 2 into which the pressure boosting valve 5a, the pressure reducing valve 5b and the pressure sensor 6 can be inserted. With this structure, for instance, the pressure sensor 6 penetrates the mid-bottom wall section 2b, and as will be described later, a terminal 6a of the pressure sensor 6 can make contact with the printed circuit board 12 by being pressed against a lower surface 12b of the printed circuit board 12 (through the contact pad 6b, in FIG. 2).

The printed circuit board 12 is formed from, for instance, synthetic resin material, and has a substantially square thin plate shape. When the printed circuit board 12 is mounted on the mid-bottom wall section 2b from above and supported and held by the snap-fits 20a to 20c, the printed circuit board 12 is set with the printed circuit board 12 being separate from the mid-bottom wall section 2b in the vertical direction according to supporting or holding positions of the snap-fits. Due to the fact that a clearance between the printed circuit board 12 and the mid-bottom wall section 2b in the vertical direction is given, the electronic components etc. mounted on the lower surface 12b of the printed circuit board 12 do not interfere with the mid-bottom wall section 2b. For example, in the case of the printed circuit board 12 shown in FIG. 2, a combine sensor 12d is mounted on the lower surface 12b, and the clearance is given between the printed circuit board 12 and the mid-bottom wall section 2b so that the combine sensor 12d does not interfere with the mid-bottom wall section 2b.

The printed circuit board 12 mounts thereon a plurality of electronic components including a microcomputer, and a power distribution pattern that is a part of a control circuit is formed on the printed circuit board 12, then, for instance, a drive control signal of the electric motor is generated by the printed circuit board 12.

The printed circuit board 12 is provided with a plurality of terminal holes 12c (see FIG. 1, but terminal holes for the terminal group 19 are not shown in FIG. 1) at one periphery and the other periphery of the printed circuit board 12. Then, pins 17a, 18a and 19a of the terminal groups 17, 18 and 19 penetrating the mid-bottom wall section 2b are inserted into the terminal holes 12c and electrically connected to the terminal holes 12c by soldering.

As shown in FIG. 2, the contact pad 6b is provided at the press-contact position of the terminal 6a of the pressure sensor 6 on the lower surface 12b of the printed circuit board 12 (i.e. at the position where the terminal 6a is pressed against the lower surface 12b of the printed circuit board 12), and the snap-fit 20a is arranged at this position where the contact pad 6b is provided. Then, the plurality of elastically-supporting parts 21 (e.g. two elastically-supporting parts 21, as shown in FIG. 4) of the supporter 210 of the snap-fit 20a make elastic contact with the lower surface 12b of the printed circuit board 12 at separated or dispersed positions with respect to the circumferential edge side of the contact pad 6b. The lower surface 12b of the printed circuit board 12 is thus elastically supported by the elastically-supporting parts 21 in this manner.

Further, as shown in FIG. 2, the nail portion 22c of the supporting hook 22 is fitted on (and catches and holds) an upper surface 12a of the printed circuit board 12. The upper surface 12a of the printed circuit board 12 is thus supported and held by the nail portion 22c in this manner.

<Example of Assembly of Printed Circuit Board>

As described above, when mounting the printed circuit board 12 on the mid-bottom wall section 2b from above, first, the circumferential edge of the lower surface 12b of the printed circuit board 12 touches the top end portion 22b of each supporting hook 22 of the snap-fits 20a to 20c.

Further, when pressing down the printed circuit board 12 as it is, the circumferential edge of the lower surface 12b of the printed circuit board 12 makes elastic contact with the nail portion 22c of the top end portion 22b of each supporting hook 22 at each position of the snap-fits 20a to 20c while being pressed down, and each supporting hook 22 is elastically deformed in an outward direction (in a direction of an outer circumference side) of the printed circuit board 12.

Subsequently, when further pressing down the printed circuit board 12, the upper surface 12a of the printed circuit board 12 moves over the nail portion 22c of each supporting hook 22 and is positioned at a lower side with respect the nail portion 22c. Each supporting hook 22 then elastically returns from the elastically deformed shape.

In this manner, the nail portion 22c of the supporting hook 22 is fitted on (and catches and holds) the upper surface 12a of the printed circuit board 12.

With this assembly, the upper surface 12a of the printed circuit board 12 is held, while the lower surface 12b of the printed circuit board 12 is elastically supported by the fact that the elastically-supporting part 21 of each supporter 210 of the snap-fits 20a to 20c makes elastic contact with the lower surface 12b of the printed circuit board 12, thereby supporting and holding the printed circuit board 12.

With respect to the terminal pins 17a and 18a of the terminal groups 17 and 18, they are inserted into the terminal holes 12c.

According to the structure, as explained above, in which the printed circuit board 12 is elastically supported (in FIGS. 1 and 2, the lower surface 12b of the printed circuit board 12 is elastically supported), even if the vibration occurs, it is possible to supporting and holding the printed circuit board 12 stably while suppressing the vibration. Also, it is possible to adequately keep a good contact state between the sensor 6 and the printed circuit board 12 while suppressing the strain of the printed circuit board 12 due to the pressing force of the sensor terminal.

Further, for instance, even if there arises a dimension error, in vertical and horizontal directions, of the base member 2, the sensor 6 and the printed circuit board 12 or an assembly error, since the snap-fit is elastically deformed, the error is absorbed, then the positioning and assembly can be facilitated.

<Other Configuration of Electronic Control Device>

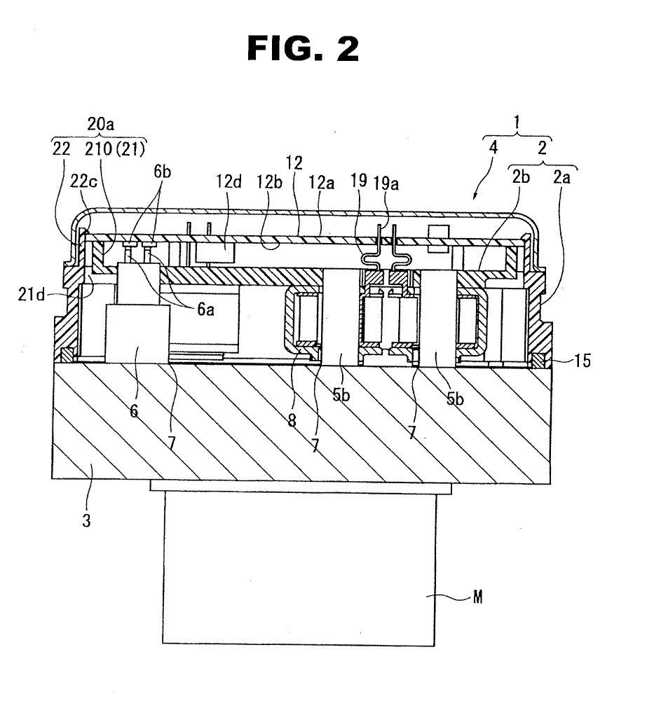

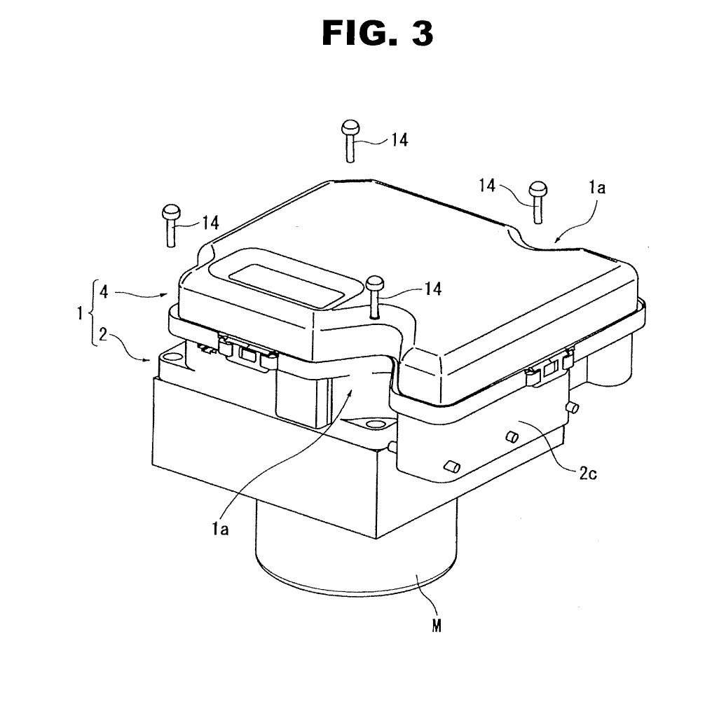

In the electronic control device shown in FIG. 3, a depressed portion is formed between the connecter wall section 2c and a side opposite to the connecter wall section 2c at the base member 2 and the cover member 4 of the enclosure 1. Then, the bolt insertion hole 11a is formed at this position where the depressed portion is formed, and the fixing bolt 14 inserted into the bolt insertion hole 11a is screwed into the female screw hole 9.

In the case of the electronic control device having such configuration, the depressed portion is also formed at the printed circuit board 12. For instance, as shown in FIG. 4, two depressed portions 12d are formed between the connecter wall section 2c and a side opposite to the connecter wall section 2c. Then, the circumferential edges located on the opposite side of the depressed portions 12d are supported and held by the snap-fits 20a to 20c.

Also in the case of the electronic control device shown in FIGS. 3 and 4, the same effects as that of the FIGS. 1 and 2 can be obtained.

From the foregoing, the present invention includes the following structure or configuration of the electronic control device, and has the following effects.

In the electronic control device, the contact pad is located between at least two elastic contact positions of the elastically-supporting parts of the snap-fit.

In the electronic control device, three sides of the four sides of the circuit board except the one side circumferential edge where the power connecter terminal is connected are supported by the snap-fits.

In the electronic control device, the elastically-supporting part has a cantilever portion that extends along the one end surface of the circuit board and a protruding portion that protrudes from a top end side of the cantilever portion in a direction of the one end surface of the circuit board, and a top end of the protruding portion makes elastic contact with the one end surface of the circuit board.

The entire contents of Japanese Patent Application No. 2013-058885 filed on Mar. 21, 2013 are incorporated herein by reference.

Although the invention has been described above by reference to certain embodiments of the invention, the invention is not limited to the embodiments described above. Modifications and variations of the embodiments described above will occur to those skilled in the art in light of the above teachings. The scope of the invention is defined with reference to the following claims.

What is claimed is:

1. An electronic control device having a circuit board on which electronic components are mounted, the electronic control device comprising:
an enclosure formed from a plurality of enclosure members and accommodating the circuit board in a space inside the enclosure; and
a plurality of snap-fits separately arranged at the enclosure member to hold the circuit board, the snap-fit having
(a) a supporter that elastically supports one end surface of the circuit board; and
(b) a supporting hook that supports the other end surface of the circuit board, and
when a sensor terminal is pressed against the one end surface of the circuit board through a contact pad at at least one of snap-fit arrangement positions, the supporter of the snap-fit positioned where the sensor terminal is pressed against the one end surface of the circuit board being provided with a plurality of elastically-supporting parts that make elastic contact with the one end surface of the circuit board at dispersed positions with respect to a circumferential edge side of the contact pad.

2. The electronic control device as claimed in claim 1, wherein:
in a case where a power connecter terminal is connected at a one side circumferential edge of four sides of the circuit board and also the circuit board has a depressed portion that is depressed toward a middle of the circuit board in a plane direction of the circuit board at a circumferential edge of the circuit board located between the power connecter terminal and an opposite side circumferential edge that is opposite to the one side circumferential edge, the opposite side of the circuit board with respect to the depressed portion is supported by the snap-fits.

3. The electronic control device as claimed in claim 1, wherein:
the enclosure has an enclosure member which spreads along the one end surface of the circuit board and on which the snap-fits are provided.

4. The electronic control device as claimed in claim 1, wherein:
the contact pad is located between at least two elastic contact positions of the elastically-supporting parts of the snap-fit.

5. The electronic control device as claimed in claim 2, wherein:
three sides of the four sides of the circuit board except the one side circumferential edge where the power connecter terminal is connected are supported by the snap-fits.

6. The electronic control device as claimed in claim 3, wherein:
the elastically-supporting part has a cantilever portion that extends along the one end surface of the circuit board and a protruding portion that protrudes from a top end side of the cantilever portion in a direction of the one end surface of the circuit board, and
a top end of the protruding portion makes elastic contact with the one end surface of the circuit board.
